(19) United States
(12) Patent Application Publication
(10) Pub. No.: US 2024/0363507 A1
(43) Pub. Date: Oct. 31, 2024

(54) SEMICONDUCTOR DEVICE, SEMICONDUCTOR MODULE, AND LEAD FRAME

(71) Applicant: FUJI ELECTRIC CO., LTD., Kanagawa (JP)

(72) Inventor: Hayato NAKANO, Kofu-city (JP)

(21) Appl. No.: 18/582,566

(22) Filed: Feb. 20, 2024

(30) Foreign Application Priority Data
Apr. 25, 2023 (JP) 2023-071867

(51) Int. Cl. H01L 23/498; H01L 21/66

(52) U.S. Cl. CPC H01L 23/49811; H01L 22/12; H01L 22/32; H01L 23/49838

(57) ABSTRACT

Provided is a semiconductor device including: a temperature sensing portion provided above a semiconductor substrate; a temperature sensing wiring portion electrically connected to the temperature sensing portion; and a protective film including a temperature sensing protective film provided above the temperature sensing portion and a first wiring protective film provided above the temperature sensing wiring portion, where the first wiring protective film includes: a first region adjacent to the temperature sensing protective film; and a second region provided more spaced apart from the temperature sensing protective film than the first region and having a width narrower than that of the first region.

The contents of the following patent application(s) are incorporated herein by reference:
NO. 2023-071867 filed in JP on Apr. 25, 2023

### BACKGROUND

### 1. Technical Field

The present invention relates to a semiconductor device, a semiconductor module, and a lead frame.

### 2. Related Art

Patent Literature 1 discloses a semiconductor module in which an electrode and a plate-shaped lead frame formed on a semiconductor device and connected to each other by a solder.

### PRIOR ART LITERATURE

### Patent Literature

Patent Literature 1: PCT Patent Application International Publication No. 2020/067059.

### BRIEF DESCRIPTION OF THE DRAWINGS

FIG. 1 is a schematic view showing an example of a semiconductor module 100 according to the example.

FIG. 2 is an example of a top view of the semiconductor chip 40 according to the example.

FIG. 3 is an example of a top view of the semiconductor chip 40 according to the example.

FIG. 4 is an example of an enlarged view of a protective film 150-7 shown in FIG. 3.

FIG. 5 is an example of a top view of the semiconductor chip 40 according to the example.

FIG. 6A is an example of a cross sectional view of a protective film 150-4 of the semiconductor module 100.

FIG. 6B is an example of a cross sectional view of the protective film 150-7 of the semiconductor module 100.

FIG. 6C is an example of a cross sectional view of a protective film 150-7 of the semiconductor module 100.

FIG. 7 is a diagram showing an example of a top view of the semiconductor chip 40 according to the comparative example.

FIG. 8 is another example of a top view of the semiconductor chip 40 according to the example.

FIG. 9A is an example of a bottom view of the chip connecting portion 62.

FIG. 9B is an example of a cross sectional view of the chip connecting portion 62.

FIG. 9C is an example of a cross sectional view of the protective film 150-7 of the semiconductor module 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention. Note that, in the present specification and the drawings, elements having substantially the same functions and configurations are denoted by the same reference numerals, and redundant descriptions for them are omitted. Also, elements not directly related to the present invention are omitted from the drawings. Further, in one drawing, elements having the same functions and configurations are denoted by a representative reference numeral, and other reference numerals for the elements may be omitted.

As used herein, one side in a direction parallel to a depth direction of a semiconductor chip is referred to as “upper” and the other side is referred to as “lower”. One surface of two main surfaces of a substrate, a layer or other member is referred to as an upper surface, and another surface is referred to as a lower surface. An “upper” or “lower” direction is not limited to the gravity direction or a direction when a semiconductor module is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis. As used herein, the orthogonal axes parallel to an upper surface and a lower surface of the semiconductor substrate are defined as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

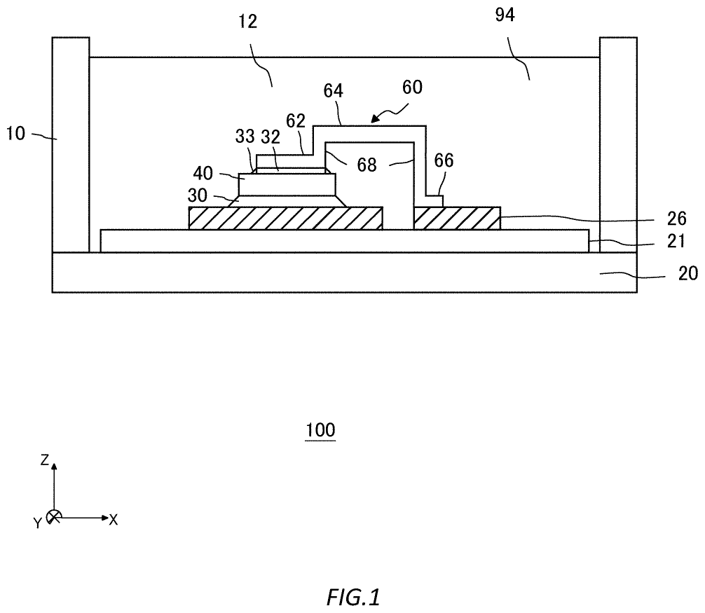

FIG. 1 is a schematic view showing an example of a semiconductor module 100 according to the example. The semiconductor module 100 may function as a power conversion apparatus such as an inverter. The semiconductor module 100 includes one or more dielectric substrates 21. Either one of surfaces of the dielectric substrate 21 is provided with a certain circuit pattern 26 while the other surface of the dielectric substrate 21 is provided with a cooling apparatus 20. The circuit pattern 26 may be configured by directly bonding or alternatively bonding with a brazing material layer, a copper plate or an aluminum plate, or alternatively, bonding via a material layer, a plate with plated copper or aluminum onto the dielectric substrate 21 of silicon nitride ceramics, aluminum nitride ceramics or the like.

One or more semiconductor chips 40 are mounted on the circuit pattern 26. The semiconductor chip 40 is an example of a semiconductor device. In the example of FIG. 1, one semiconductor chip 40 is mounted. The solder portion 30 bonds the semiconductor chip 40 to the circuit pattern 26. The semiconductor chip 40 is protected by a resin package such as a resin casing 10 surrounding the dielectric substrate 21 and a sealing resin 12 filled in the resin casing 10. Note that the semiconductor chip 40 or the like may be protected by, rather than providing the resin casing 10, transfer molding with the sealing resin 12 or the like.

The semiconductor chip 40 may include an IGBT, a diode such as an FWD (Free Wheel Diode), an RC (Reverse Conducting)-IGBT which is a combination thereof, and an MOS transistor or the like. An amount of heat generation of the semiconductor chip 40 varies depending on the operating state. For example, an amount of heat generation of an RC-IGBT varies because a conducting portion when the IGBT is an ON state is different from a conducting portion when the IGBT is in an OFF state where a current flows in the FWD. Thus, a temperature rise and a temperature drop occur when the semiconductor chip 40 is switched.

The semiconductor chip 40 of the present example is a vertical chip in which electrodes (for example, an emitter electrode and a collector electrode) are formed on an upper surface and a lower surface. The semiconductor chip 40 is connected to the circuit pattern 26 through an electrode formed on the lower surface and connected to a wiring member through an electrode formed on the upper surface. Note that the semiconductor chip 40 is not limited to a vertical chip. The semiconductor chip 40 may have an electrode connected to the circuit pattern 26 in the upper surface.

The resin casing 10 is provided to surround a space 94 for accommodating the semiconductor chip 40. The dielectric substrate 21 is provided below the resin casing 10. Note that the space 94 may be a region above the dielectric substrate 21 and a region surrounded by the resin casing 10.

In the present example, the resin casing 10 is molded with resin such as a thermosetting resin formable by injection molding or ultraviolet curable resin formable by UV molding. The resin may include, for example, one or more polymer materials selected from polyphenylene sulfide (PPS) resin, polybutylene terephthalate (PBT) resin, polyamide (PA) resin, acrylonitrile butadiene styrene (ABS) resin, acrylic resin, and the like.

The cooling apparatus 20 includes a coolant such as water therein. The cooling apparatus 20 cools the semiconductor chip 40 via the dielectric substrate 21 or the like. In addition, a heat release plate may be provided between the cooling apparatus 20 and the dielectric substrate 21. The cooling apparatus 20 may cool the semiconductor chip 40 via the heat release plate.

The semiconductor chip 40 is connected to a wiring member via a solder portion 32 having an upper surface working as a bonding member. The wiring member of the present example is a lead frame 60. The lead frame 60 is a member formed of a metal material such as copper or aluminum. At least a part of the surface of the lead frame 60 may be plated with nickel or the like. In addition, at least a part of the surface of the lead frame 60 may be coated with resin or the like. The lead frame 60 may include a plate-shaped portion. The plate shape refers to a shape in which the areas of two main surfaces disposed opposite to each other are larger than the areas of the other surfaces. At least a portion of the lead frame 60 connected to the semiconductor chip 40 may have a plate shape. The lead frame 60 may be formed by bending one metal plate.

The lead frame 60 electrically connects the semiconductor chip 40 and the circuit pattern 26. The main current may flow through the lead frame 60. Here, the main current is the largest current of currents flowing through the semiconductor chip 40. The lead frame 60 of the present example includes a chip connecting portion 62, a bridge portion 64, a circuit pattern connecting portion 66 and a leg portion 68. The chip connecting portion 62 is a portion connecting to the upper surface of the semiconductor chip 40. A lower surface of the chip connecting portion 62 connecting to the upper surface of the semiconductor chip 40 may be referred to as a bonding surface. The circuit pattern connecting portion 66 is portion connected to the upper surface of the circuit pattern 26. The chip connecting portion 62 and the circuit pattern connecting portion 66 may be plate-shaped portions substantially parallel to the XY plane. Therefore, the chip connecting portion 62 and the circuit pattern connecting portion 66 may be plate-shaped portions substantially parallel to the upper surface of the semiconductor chip 40. Note that being substantially parallel refers to, for example, a state in which an angle formed by two members is equal to or smaller than 10 degrees.

The leg portion 68 is a portion extending in the Z axis direction. The bridge portion 64 connects the chip connecting portion 62 and the circuit pattern connecting portion 66 via the leg portion 68. The bridge portion 64 is disposed apart from the conductive member such as the circuit pattern 26. The bridge portion 64 of the present example is disposed above the circuit pattern 26 or the like, and is provided from the chip connecting portion 62 to the circuit pattern connecting portion 66 so as to straddle the circuit pattern 26 or the like.

In the present example, the sealing resin 12 is provided in the resin casing 10. The sealing resin 12 seals the semiconductor chip 40 and the lead frame 60 as a wiring member. That is, the sealing resin 12 entirely covers the semiconductor chip 40 and the lead frame 60 so that the semiconductor chip 40 and the lead frame 60 are not exposed. The sealing resin 12 can protect the semiconductor chip 40 and the lead frame 60.

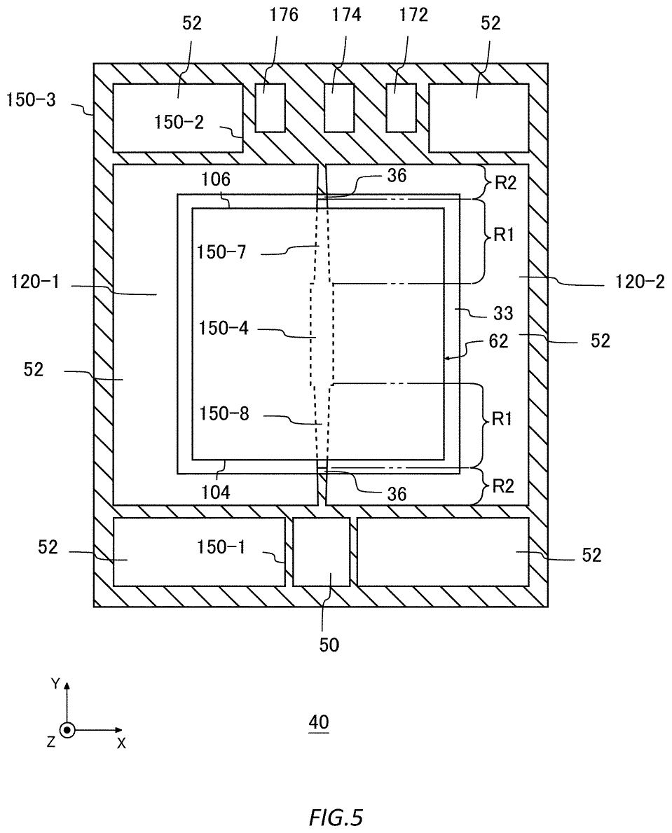

The solder portion 32 is provided between the upper surface of the semiconductor chip 40 and the lower surface of the chip connecting portion 62 of the lead frame 60 so that the semiconductor chip 40 and the chip connecting portion 62 are mechanically and electrically connected to each other. The solder portion 32 includes a fillet portion 33. The fillet portion 33 is a portion provided at the end portion of the solder portion 32 and having a flared shape. The fillet portion 33 may be a portion of the solder portion 32 which is not overlapped with the chip connecting portion 62 in a top view (refer to FIG. 5). In the present example, lead-free solder is used for the solder portion 32. The lead-free solder contains as a main component, for example, at least any alloy of a tin-silver-copper alloy, a tin-zinc-bismuth alloy, a tin-copper alloy, and a tin-silver-indium-bismuth alloy. In addition, as a bonding member like this, a metal sintered object may also be used instead of the solder portion 32. The metal sintered object is an alloy including silver, gold, nickel, copper, or at least one kind of them.

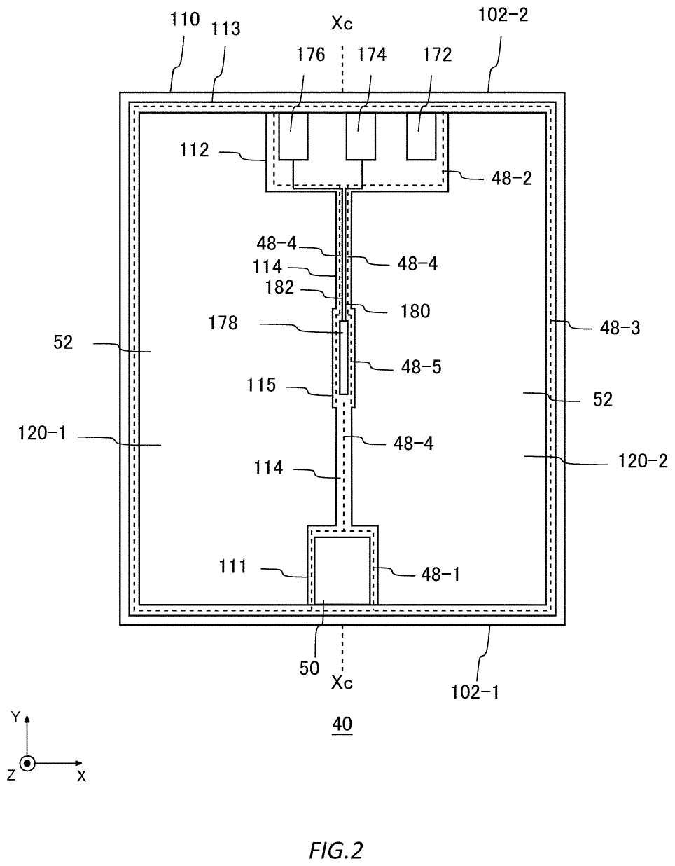

FIG. 2 is an example of a top view of the semiconductor chip 40 according to the example. The semiconductor chip 40 includes a semiconductor substrate 110. The semiconductor substrate 110 is a substrate formed of a semiconductor material such as silicon or a compound semiconductor. The semiconductor substrate 110 has an end side 102 in the top view. The semiconductor substrate 110 in the present example has two sets of end sides 102 facing each other in a top view. In FIG. 1, a pair of the end side 102-1 and the end side 102-2 facing each other is shown. In FIG. 1, a direction parallel to the end side 102-1 and the end side 102-2 is referred to as an X axis direction, and a direction perpendicular to the end side 102-1 and the end side 102-2 is referred to as a Y axis direction.

The semiconductor substrate 110 is provided with an active portion 120. In the present example, the semiconductor substrate 110 is provided with an active portion 120-1 and an active portion 120-2. The active portion 120 refers to a region in which a main current flows in the depth direction between the upper surface and the lower surface of the semiconductor substrate 110 when the semiconductor chip 40 is controlled to be in an ON state. Accordingly, a region between the well regions in FIG. 2 may be referred to as the active portion 120. The active portion 120 may be provided with a transistor portion including a transistor device such as an IGBT. The active portion 120 may also be provided with a diode portion including a diode device such as an FWD. The active portion 120 may be a region in which at least one of the transistor portion and the diode portion is provided. The active portion 120 may be a region which overlaps with an upper surface main electrode in a top view. The upper surface main electrode may be an electrode which occupies the largest area in a top view among electrodes disposed above the upper surface of the semiconductor substrate 110. The upper surface main electrode may be electrically connected to an emitter region or a source region of the transistor portion, and may be electrically connected to an anode region of the diode portion. In the example of FIG. 2, the emitter electrode 52 is the upper surface main electrode.

The semiconductor substrate 110 is provided with a P type well region. The well region is a P type region having a higher concentration than a base region of the transistor portion or the anode region of the diode portion. The base region is a P type region which is positioned opposite to a gate electrode, and which has a channel formed on a portion opposite to the gate electrode when a predetermined gate voltage is applied to the gate electrode. The semiconductor chip 40 includes a first well region 111 and a second well region 112. The first well region 111 and the second well region 112 are disposed to sandwich the active portion 120 in a top view. The first well region 111 and the second well region 112 are disposed to sandwich the active portion 120 in a predetermined direction (in FIG. 2, in the Y axis direction). To sandwich the active portion 120 by the two well regions refers to that any straight line connecting the two well regions in a top view passes through the active portion 120.

The first well region 111 may be disposed in vicinity of the end side 102-1. That is, a distance between the first well region 111 and the end side 102-1 is smaller than a distance between the first well region 111 and the end side 102-2. The second well region 112 may be positioned in vicinity of the end side 102-2. That is, a distance between the second well region 112 and the end side 102-2 is smaller than a distance between the second well region 112 and the end side 102-1.

The first well region 111 of the present example is positioned in the Y axis direction between the active portion 120 and the end side 102-1. The active portion 120 is not provided between the first well region 111 and the end side 102-1. That is, the first well region 111 is positioned between the end portion of the active portion 120 in the Y axis direction and the end side 102-1.

The second well region 112 of the present example is positioned in the Y axis direction between the active portion 120 and the end side 102-2. The active portion 120 is not provided between the second well region 112 and the end side 102-2. That is, the second well region 112 is positioned between the end portion of the active portion 120 in the Y axis direction and the end side 102-2.

The first well region 111 and the second well region 112 may be provided, in the X axis direction, in a range including a center position Xc of the end side 102-1 and the end side 102-2. The first well region 111 may be sandwiched between the active portions 120 in the X axis direction. The second well region 112 may be sandwiched between the active portions 120 in the X axis direction. The second well region 112 may be provided in a wider range in the X axis direction than the first well region 111.

The semiconductor chip 40 may include a peripheral well region 113 disposed to surround the active portion 120 in a top view. The peripheral well region 113 may be provided parallel to respective end sides of the semiconductor substrate 110. The peripheral well region 113 of the present example is an annular region surrounding the active portion 120 in a top view. The peripheral well region 113 may have a constant width in a direction perpendicular to the respective end sides.

The first well region 111 and the second well region 112 of the present example protrude farther to the center side of the semiconductor chip 40 than the peripheral well region 113 does. In another example, at least one of the first well region 111 and the second well region 112 may be positioned between the peripheral well region 113 and the end side 102 of the semiconductor substrate 110. In this case, the first well region 111 and the second well region 112 protrude from the peripheral well region 113 to the end side 102 side.

The semiconductor chip 40 may include a dividing well region 114 which divides the active portion 120 in a top view. Because of a well region including the dividing well region 114, the active portion 120 may be divided into the active portion 120-1 and the active portion 120-2. The dividing well region 114 has a longitudinal part in a predetermined well longitudinal direction. The dividing well region 114 extends in the well longitudinal direction to traverse the semiconductor chip 40. The well longitudinal direction of the dividing well region 114 is the Y axis direction.

The dividing well region 114 may be provided between the first well region 111 and the second well region 112. One end in the longitudinal direction of the dividing well region 114 may be connected to the first well region 111, and the other end may be connected to the second well region 112. The dividing well region 114 may be provided in a region which overlaps with the center of the semiconductor chip 40.

The dividing well region 114 may include a wider portion 115 whose width in a direction perpendicular to the well longitudinal direction in a top view (in the present example, X axis direction) is wider than those of the other portions. The wider portion 115 is also provided between the first well region 111 and the second well region 112. The wider portion 115 may be provided in a region which overlaps with the center of the semiconductor chip 40. The wider portion 115 may be positioned in a region including a center in the well longitudinal direction of the dividing well region 114.

The semiconductor chip 40 of the present example includes pad electrodes such as a gate pad 50, a current detection pad 172, an anode pad 174, and a cathode pad 176. The gate pad 50 is an example of a first pad region disposed above the first well region 111. The current detection pad 172, the anode pad 174 and the cathode pad 176 are an example of a second pad region disposed above the second well region 112.

A temperature sensing portion 178 is a PN junction diode formed of a semiconductor material such as polysilicon. The temperature sensing portion 178 is provided at the center of the semiconductor substrate 110 in a top view. That is, the temperature sensing portion 178 is disposed above the wider portion 115. That is, at least a part of the temperature sensing portion 178 and at least a part of the wider portion 115 are overlapped. A region occupying a half or more of the temperature sensing portion 178 of the present example in a top view is overlapped with the wider portion 115. The temperature sensing portion 178 may overlap with the wider portion 115 as a whole.

The wider portion 115 is not provided with the active portion 120. If the active portions of the semiconductor chip 40 are integrated, the center portion of the semiconductor chip 40 in a top view tends to be heated due to the heat generation from switching devices provided in the active portions. The temperature sensing portion 178 is provided in the wider portion 115 at the center of the semiconductor chip 40 such that the semiconductor chip 40 can be prevented from being overheated over the normal operation temperature range.

The emitter electrode 52 and each pad electrode are electrodes including a metal such as aluminum. An interlayer dielectric film 38 is provided between the emitter electrode 52 and each pad electrode and the semiconductor substrate 110. The emitter electrode 52 and each pad electrode and the semiconductor substrate 110 are connected to each other via a contact hole provided in the interlayer dielectric film 38. In FIG. 2, the interlayer dielectric film 38 and the contact hole are omitted.

The emitter electrode 52 is positioned above the active portion 120. The emitter electrode 52 is connected to the active portion 120 via the contact hole described above. A wiring member is connected to the upper surface of the emitter electrode 52, and a predetermined emitter voltage is applied thereto. The emitter electrode 52 and each pad electrode are provided to be separated from each other in a top view. A wire or the like is connected to the upper surface of each pad electrode. The emitter electrode 52 may be provided for each of the active portion 120-1 and the active portion 120-2.

A predetermined gate voltage is applied to the gate pad 50. The gate voltage applied to the gate pad 50 is supplied to the transistor portion of the active portion 120 by a gate runner or the like described below. The gate pad 50 is positioned above the first well region 111. That is, at least a part of the gate pad 50 and at least a part of the first well region 111 are overlapped. A region occupying half or more of the gate pad 50 of the present example in a top view is overlapped with the first well region 111. The gate pad 50 may overlap with the first well region 111 as a whole. The gate pad 50 of the present example may be disposed in the vicinity of the end side 102-1 of the semiconductor chip 40. That is, the gate pad 50 is disposed between the emitter electrode 52 and the end side 102-1 of the semiconductor chip 40, while the emitter electrode 52 is not disposed between the gate pad 50 and the end side 102-1. The gate pad 50 may be disposed in a region including the center position Xc of the end side 102-1 of the semiconductor chip 40 in the X axis direction.

The current detection pad 172 is connected to a current detection portion (not shown) and detects a current flowing in the current detection portion. The anode pad 174 is connected to the anode region of the temperature sensing portion 178 via the anode wiring 180. The cathode pad 176 is connected to the cathode region of the temperature sensing portion 178 via the cathode wiring 182. The anode pad 174 and the cathode pad 176 are an example of a temperature sensing pad, while the anode wiring 180 and the cathode wiring 182 are an example of a temperature sensing wiring portion.

The current detection pad 172, the anode pad 174 and the cathode pad 176 are disposed above the second well region 112. For each pad electrode of the current detection pad 172, the anode pad 174 and the cathode pad 176, at least a part of the pad electrode and at least a part of the second well region 112 are overlapped with each other. Regions occupying a half or more of the current detection pad 172, the anode pad 174, and the cathode pad 176 of the present example in a top view overlap with the second well region 112. The current detection pad 172, the anode pad 174, and the cathode pad 176 may overlap with the second well region 112 as a whole.

Each pad electrode of the current detection pad 172, the anode pad 174 and the cathode pad 176 of the present example may be disposed in the vicinity of the end side 102-2 of the semiconductor chip 40. That is, each pad electrode of the current detection pad 172, the anode pad 174 and the cathode pad 176 is disposed between the emitter electrode 52 and the end side 102-2 of the semiconductor chip 40, while the emitter electrode 52 is not disposed between the each pad electrode and the end side 102-2. In addition, each pad electrode may be disposed in a region including the center position Xc of the end side 102-2 of the semiconductor chip 40 in the X axis direction.

The gate pad 50 and each pad electrode of the current detection pad 172, the anode pad 174 and the cathode pad 176 of the present example may be disposed at the opposing end sides 102-1 and 102-2 of the semiconductor chip 40, respectively, and may be disposed to oppose each other via the dividing well region 114.

In FIG. 2, the gate runner 48 is shown in a dashed line. The gate runner 48 is a wiring formed of a conductive material such as polysilicon with impurity added thereto, or metal. The gate runner 48 supplies a gate voltage applied to the gate pad 50 to the transistor portion provided in the active portion 120. The gate runner 48 may be positioned above the well region. The gate runner 48 is an example of the gate wiring portion.

The semiconductor chip 40 may include a gate runner 48-3 disposed to surround the active portion 120 in a top view. The gate runner 48-3 may be positioned above the peripheral well region 113.

The semiconductor chip 40 may include a gate runner 48-1 surrounding at least a part of regions of the first well region 111 in a top view. The gate runner 48-1 may be positioned along end sides of the first well region 111 in a top view. The gate runner 48-1 may include portions parallel to the respective end sides of the first well region 111.

The semiconductor chip 40 may include a gate runner 48-2 surrounding at least a part of regions of the second well region 112 in a top view. The gate runner 48-2 may be positioned along end sides of the second well region 112 in a top view. The gate runner 48-2 may include portions parallel to the respective end sides of the second well region 112.

The semiconductor chip 40 may include a gate runner 48-4 disposed above the dividing well region 114 in a top view. The semiconductor chip 40 may include a gate runner 48-5 surrounding at least a part of regions of the wider portion 115 in a top view. The gate runner 48-5 may be positioned along an end side of the wider portion 115 in a top view. The gate runner 48-5 may include portions parallel to the respective end sides of the wider portion 115. The gate runner 48-4 and the gate runner 48-5 may divide the active portion 120 in a top view.

The semiconductor chip 40 may also include an edge termination structure between the peripheral well region 113 and the end sides of the semiconductor substrate 110. The edge termination structure portion reduces electric field strength on an upper surface side of the semiconductor substrate 110. The edge termination structure is structured by, for example, a guard ring provided in an annular shape surrounding the active portion 120, a field plate, an RESURF, and a combination thereof.

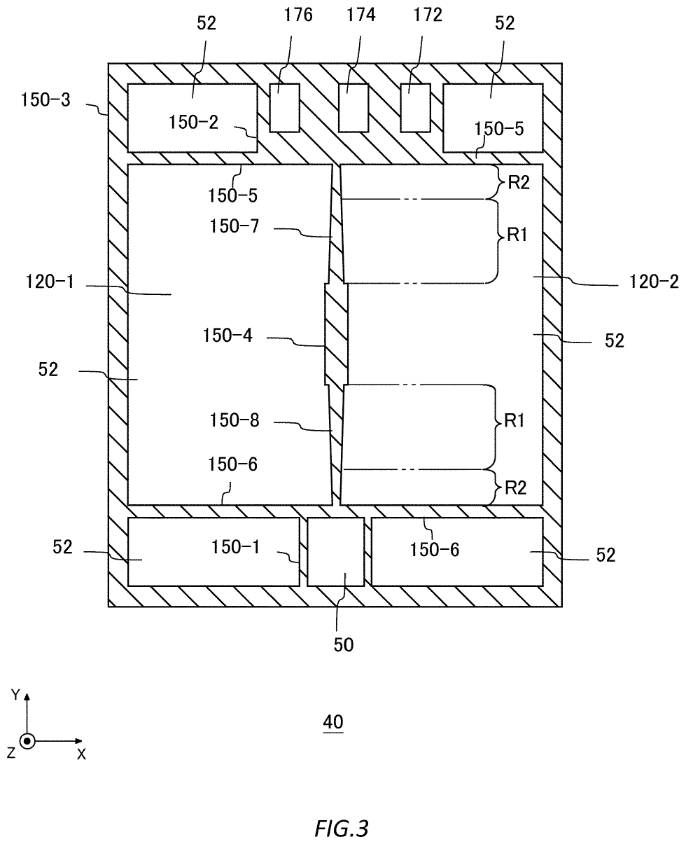

FIG. 3 is an example of a top view of the semiconductor chip 40 according to the example. The semiconductor chip 40 includes a protective film 150. In FIG. 3, a region in which the protective film 150 is disposed is indicated by hatching of diagonal lines. The protective film 150 may be provided above the emitter electrode 52 and above the semiconductor substrate 110. The protective film 150 may be in contact with an upper surface of the emitter electrode 52. The protective film 150 is provided such that the upper surface of the semiconductor chip 40 can be protected. The protective film 150 is, as an example, a polyimide film.

The semiconductor chip 40 may include a protective film 150-1 covering the first well region 111. The protective film 150-1 may expose a part of the upper surface of the gate pad 50. In this way, a wire or the like can be connected to the upper surface of the gate pad 50.

The semiconductor chip 40 may include a protective film 150-2 covering the second well region 112. The protective film 150-2 may expose a part of the upper surfaces of the current detection pad 172, the anode pad 174 and the cathode pad 176. In this way, a wire or the like can be connected to the upper surfaces of the current detection pad 172, the anode pad 174, and the cathode pad 176.

The semiconductor chip 40 may include a protective film 150-3 covering the peripheral well region 113. The protective film 150-3 may cover the entire peripheral well region 113. The protective film 150-3 is an example of a peripheral protective film. The semiconductor chip 40 may include a protective film 150-5 and a protective film 150-6 dividing the upper surface of the semiconductor substrate 110. The protective film 150-5 and the protective film 150-6 may be provided to traverse the upper surface of the semiconductor substrate 110 in the X axis direction. In the present example, the protective film 150-5 is provided to connect to the protective film 150-2, while the protective film 150-6 is provided to connect to the protective film 150-1.

The semiconductor chip 40 may include a protective film 150-4, a protective film 150-7 and a protective film 150-8 covering the dividing well region 114. The protective film 150-4, the protective film 150-7 and the protective film 150-8 may cover the entire dividing well region 114. In the present example, the protective film 150-4 covers the entire wider portion 115, the protective film 150-7 covers the dividing well region 114 between the wider portion 115 and the protective film 150-5, and the protective film 150-8 covers the dividing well region 114 between the wider portion 115 and the protective film 150-6.

The protective film 150-4 is an example of the temperature sensing protective film, the protective film 150-7 is an example of the first wiring protective film, and the protective film 150-8 is an example of the second wiring protective film. That is, the protective film 150-4 is provided above the temperature sensing portion 178, the protective film 150-7 is provided above the temperature sensing wiring portion (the anode wiring 180 and the cathode wiring 182), and the protective film 150-8 is provided above the gate runner 48-4. The protective film 150-7 may be provided above the temperature sensing wiring portion and the gate runner 48-4.

The protective film 150-7 and the protective film 150-8 extend from the protective film 150-4 in different directions. In the present example, the protective film 150-7 extends from the protective film 150-4 in the +Y axis direction to connect to the protective film 150-5, while the protective film 150-8 extends from the protective film 150-4 in the −Y axis direction to connect to the protective film 150-1.

The protective film 150 exposes a part of the upper surface of the emitter electrode 52. In this way, a wire or the like can be easily connected to the upper surface of the emitter electrode 52.

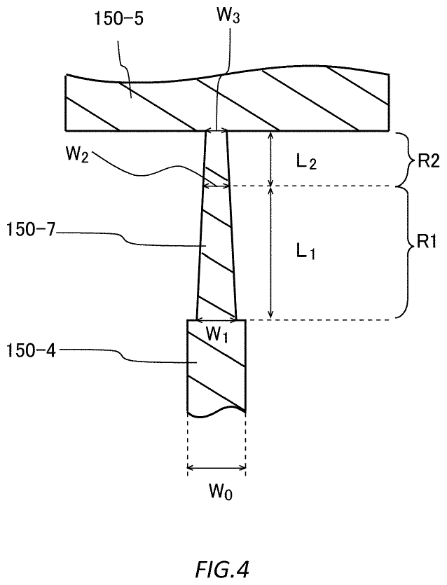

FIG. 4 is an example of an enlarged view of a protective film 150-7 shown in FIG. 3. The protective film 150-7 of the present example includes a first region R1 adjacent to the protective film 150-4, and a second region R2 provided to be more spaced apart from the protective film 150-4 than the first region R1 and having a width narrower than that of the first region R1. The second region R2 is adjacent o the protective film 150-5. Here, the width refers to a distance in a direction orthogonal to an extending direction of the protective film 150-7 (the X axis direction in the present example).

The width of the protective film 150-7 of the present example gradually decreases as being more spaced apart from the protective film 150-4. The protective film 150-7 of the present example has a trapezoidal shape in a top view. Alternatively, the protective film 150-7 may also have a tapered shape. The width W₁ of an end portion of the protective film 150-4 side of the first region R1 may be equal to or smaller than the width W₀ of the protective film 150-4. The width W₂ of the boundary of the first region R1 and the second region R2 is equal to or greater than the width of the temperature sensing wiring portion, and is smaller than the width W₀ of the protective film 150-4. The width W₁ is equal to or greater than 20 μm and equal to or smaller than 500 μm, while the width W₂ is equal to or greater than 10 μm and equal to or smaller than 500 μm.

The width of the first region R1 is equal to or greater than 20 μm and equal to or smaller than 500 μm, while the width of the second region R2 is equal to or greater than 5 μm and equal to or smaller than 500 μm. In the Y axis direction, the length L1 of the first region R1 is equal to or greater than 300 μm and equal to or smaller than 3000 μm, while the length L2 of the second region R2 is equal to or greater than 500 μm and equal to or smaller than 5000 μm.

Similarly, the width of the protective film 150-8 also gradually decreases as being more spaced apart from the protective film 150-4. The protective film 150-8 of the present example includes a first region R1 adjacent to the protective film 150-4, and a second region R2 provided to be more spaced apart from the protective film 150-4 than the first region R1 and having a width narrower than that of the first region R1. The second region R2 of the protective film 150-8 is adjacent to the protective film 150-6.

FIG. 5 is an example of a top view of the semiconductor chip 40 according to the example. FIG. 5 shows an example arrangement of the solder portion 32 (the fillet portion 33 in FIG. 5) and the chip connecting portion 62 of the lead frame 60 on the semiconductor chip 40. In FIG. 5, the protective film 150 overlapping the chip connecting portion 62 is indicated by a dotted line.

The chip connecting portion 62 includes an end side in a top view. The chip connecting portion 62 of the present example includes two sets of the end sides opposing to each other in a top view. One end side is a side disposed on the same straight line in a top view. FIG. 5 shows a pair of a first end side 104 and a second end side 106 opposing to each other. The first end side 104 of the chip connecting portion 62 opposes to the gate pad 50. The first end side 104 is an end side closest to the gate pad 50, from among the end sides of the chip connecting portion 62. The second end side 106 of the chip connecting portion 62 opposes to the current detection pad 172, the anode pad 174 and the cathode pad 176. The second end side 106 is an end side opposite to the first end side 104. The second end side 106 may be an end side closest to any of the current detection pad 172, the anode pad 174 and the cathode pad 176, from among the end sides of the chip connecting portion 62.

When the lead frame 60 is connected to the semiconductor chip 40 via the solder portion 32, a part of the protective film 150-4, the protective film 150-7 and the protective film 150-8 contacts the chip connecting portion 62 of the lead frame 60. When a non-metallic film such as a polyimide film is used as the protective film 150, a void such as air is generated between the protective film 150 and the chip connecting portion 62 because of the low solder wettability of the protective film 150. If a void exists between the protective film 150 and the chip connecting portion 62, the solder scattering occurs when the decompression process is performed in the thermal treatment apparatus, for example. If a solder is scattered onto the pad electrode, the reliability of connection between the pad electrode and a wire or the like is lowered. In addition, the solder scattering may allow the pad region to connect to the emitter electrode 52.

The protective film 150-7 and the protective film 150-8 of the present example include the second region R2 having a width narrower than that of the first region R1. The second region R2 of the present example is adjacent to the protective film 150-2 and the protective film 150-1. At least a part of the second region R2 is provided below the fillet portion 33.

As described above, because of the low solder wettability of the protective film 150, the solder portion 32 is not provided on the protective film 150-4. Similarly, the fillet portion 33 is not provided on the first region R1 of the protective film 150-7 and the protective film 150-8 either.

On the other hand, above the second region R2 of the protective film 150-7 and the protective film 150-8 having a width narrower than that of the first region R1, a solder bridge 36 is provided to extend from the fillet portion 33. The second region R2 of the present example is a region in which the solder bridge 36 is formed. The solder bridge 36 of the present example is provided at an end portion of the fillet portion 33 in the Y axis direction. In another example, the solder bridge 36 may be provided to extend along an extending direction of the second region R2 of the protective film 150-7 and the protective film 150-8 (the Y axis direction) from the end portion of the fillet portion 33 to the solder portion 32.

The solder bridge 36 is formed from solder remaining on the protective film 150 when the chip connecting portion 62 is connected to the semiconductor chip 40 via the solder portion 32. The solder bridge 36 prevents solder from being scattered from the protective film 150-4 side during the thermal treatment and prevents it from being scattered onto the pad electrode. Thus, the reliability of connection between these pad electrodes and wires can be maintained, and in addition, a defective connection of the current detection pad 172, the anode pad 174 or the cathode pad 176 and the emitter electrode 52 can be suppressed. A thickness of the solder bridge 36 may be equal to or greater than 20 μm and equal to or smaller than 500 μm. Here, the thickness refers to a distance between an upper end and a lower end in the depth direction of the semiconductor substrate 110 (the Z axis direction).

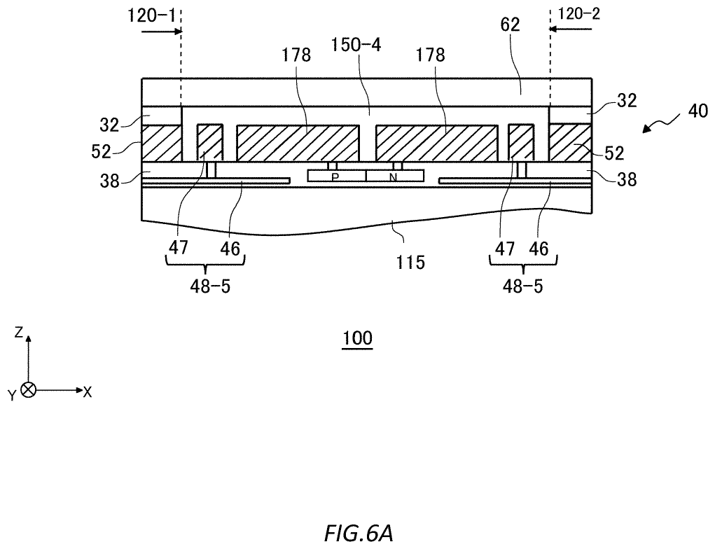

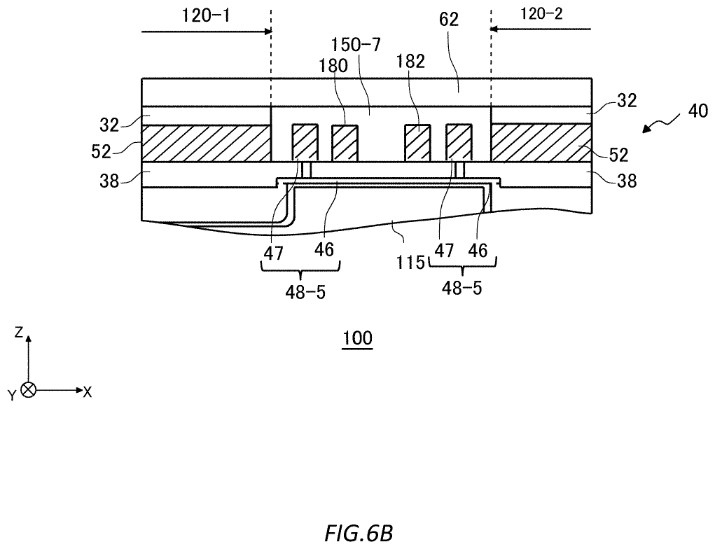

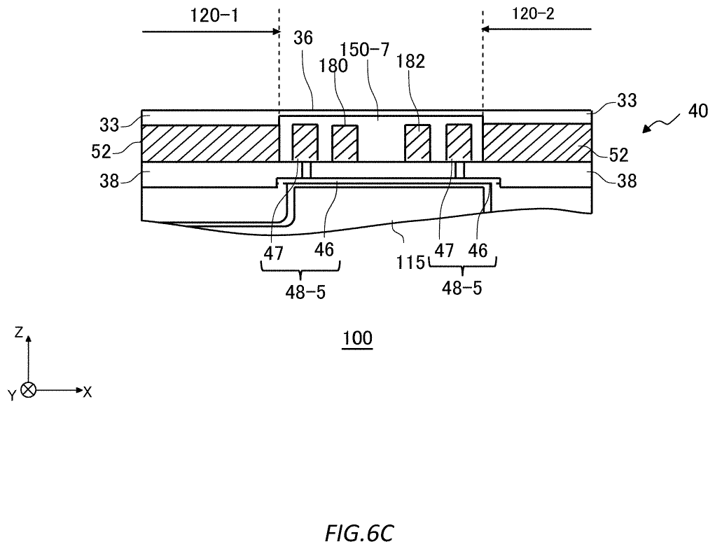

FIG. 6A is an example of a cross sectional view of a protective film 150-4 of the semiconductor module 100. FIG. 6A is an XZ plane passing through the protective film 150-4, the chip connecting portion 62, the solder portion 32, the emitter electrode 52, the temperature sensing portion 178 and the gate runner 48-4.

The temperature sensing portion 178 includes a PN junction diode by polysilicon provided above the semiconductor substrate 110 via the interlayer dielectric film 38. The gate runner 48-4 is branched in the vicinity of the PN junction diode to extend to surround the PN junction diode. This makes sure that the gate runner 48-4 is insulated from the temperature sensing portion 178.

The gate runner 48-4 of the present example includes a polysilicon wiring 46 electrically connected to the gate electrode and a metal wiring 47 extending above the polysilicon wiring 46 and electrically connected to the polysilicon wiring 46 via the contact hole. In another example, the gate runner 48-4 may also include only either one of the polysilicon wiring 46 or the metal wiring 47.

The protective film 150-4 of the present example is provided above the temperature sensing portion 178 and the metal wiring 47. The chip connecting portion 62 is provided above the protective film 150-4 and the emitter electrode 52. The emitter electrode 52 is electrically connected to the chip connecting portion 62 via the solder portion 32. On the other hand, the solder portion 32 is not provided between the chip connecting portion 62 and the protective film 150-4 so that an upper surface of the protective film 150-4 is in direct contact with a lower surface of the chip connecting portion 62. This is because the protective film 150-4 is formed of polyimide or the like having a low solder wettability. Note that a void such as air may be generated between the protective film 150-4 and the chip connecting portion 62.

FIG. 6B is an example of a cross sectional view of a protective film 150-7 of the semiconductor module 100. FIG. 6B is an XZ plane passing through the first region R1 of the protective film 150-7, the chip connecting portion 62, the solder portion 32, the emitter electrode 52, the anode wiring 180, the cathode wiring 182 and the gate runner 48-4. Note that the XZ plane passing through the first region R1 of the protective film 150-8 is the same as the XZ plane passing through the first region R1 of the protective film 150-7, aside from the anode wiring 180 and the cathode wiring 182 being not included, and therefore the illustration thereof is omitted.

The protective film 150-7 of the present example is provided above the anode wiring 180, the cathode wiring 182, and the gate runner 48-4. The width of the protective film 150-7 gradually decreases as being more spaced apart from the protective film 150-4. The width of the first region R1 is equal to or smaller than the width of the protective film 150-4. The chip connecting portion 62 is provided above the protective film 150-7 and the emitter electrode 52. In the first region R1, the solder portion 32 is not provided between the chip connecting portion 62 and the protective film 150-7 so that an upper surface of the protective film 150-7 is in direct contact with a lower surface of the chip connecting portion 62. Therefore, similarly to the protective film 150-4, a void such as air may be generated between the protective film 150-7 and the chip connecting portion 62.

FIG. 6C is an example of a cross sectional view of a protective film 150-7 of the semiconductor module 100. FIG. 6C is an XZ plane passing through the second region R2 of the protective film 150-7, the fillet portion 33, the emitter electrode 52, the anode wiring 180, the cathode wiring 182, and the gate runner 48-4. Note that the XZ plane passing through the second region R2 of the protective film 150-8 is the same as the XZ plane passing through the second region R2 of the protective film 150-7, aside from the anode wiring 180 and the cathode wiring 182 being not included, and therefore the illustration thereof is omitted.

The width of the second region R2 is narrower than the width of the first region R1. In the second region R2, the solder bridge 36 is provided above the protective film 150-7 to extend from the fillet portion 33. The solder bridge 36 of the present example is provided at an end portion of the fillet portion 33 in the Y axis direction. A thickness of the solder bridge 36 may be equal to or greater than 20 μm and equal to or smaller than 500 μm. Note that the solder bridge 36 may also be provided to extend along an extending direction of the second region R2 (the Y axis direction) from the end portion of the fillet portion 33 to the solder portion 32. In this case, the solder bridge 36 is provided between the lower surface of the chip connecting portion 62 and the upper surface of the protective film 150-7.

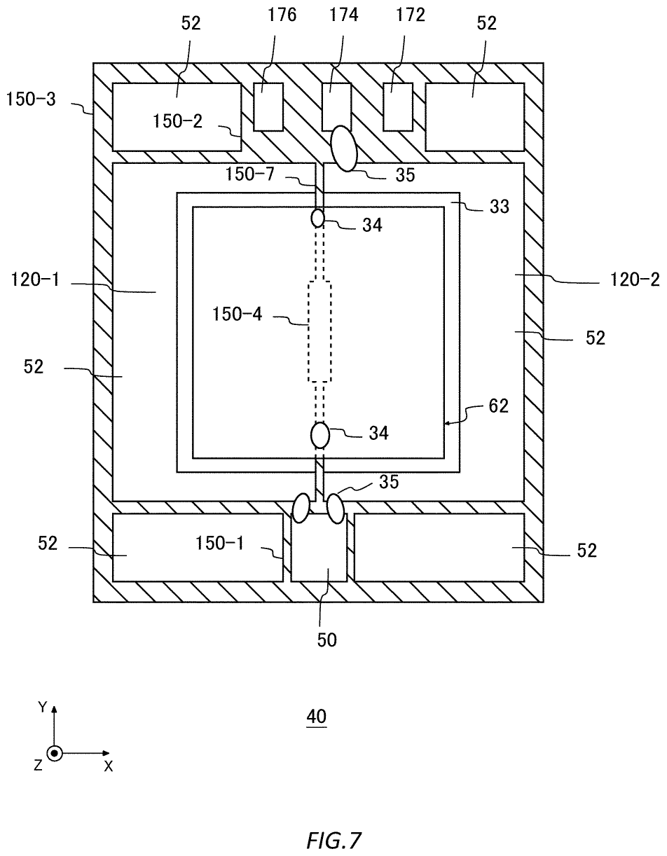

FIG. 7 is a diagram showing an example of a top view of the semiconductor chip 40 according to the comparative example. Here, a member common with the semiconductor chip 40 according to the example is indicated by the same sign and the description thereof is omitted. The protective film 150-7 and the protective film 150-8 according to the comparative example have a constant width.

When a non-metallic film such as a polyimide film is used as the protective film 150, a void 34 such as air may be generated between the protective film 150 and the chip connecting portion 62 because of the low solder wettability of the protective film 150. In addition, a small amount of solder may remain between the protective film 150 and the chip connecting portion 62. In particular, at the center of the semiconductor chip 40, there is a possibility that the void 34 is generated and the solder remains on the protective film 150-4 occupying a relatively large area.

If the decompression process is performed in the thermal treatment apparatus while the void 34 exists on the protective film 150-4, the void 34 bursts to scatter the solder remaining on the protective film 150. The solder scattering 35 propagates on the protective film 150-7 and the protective film 150-8 connected to the protective film 150-4 and reaches the protective film 150-2 and the protective film 150-1. As a result, in the comparative example of FIG. 7, via the solder scattering 35, the gate pad 50 and the emitter electrode 52 are connected to each other while the anode pad 174 and the emitter electrode 52 are connected to each other. That is, the solder scattering 35 may connect the pad region and the emitter electrode 52 so that a defect is generated.

On the other hand, according to the semiconductor chip 40 according to the example, the solder bridge 36 provided above the second region R2 of the protective film 150-7 and the protective film 150-8 can prevent the solder scattering 35.

Note that the width of the protective film 150-7 and the protective film 150-8 according to the comparative example could be narrower to form the solder bridge 36 above them. However, if the entire width of the protective film 150-7 and the protective film 150-8 is narrower constantly, it is difficult to control a region in which the solder bridge 36 is formed and the solder bridges 36 may be formed randomly at a plurality of positions along the protective film 150-7 and the protective film 150-8. In this case, the burst void 34 may blow off the randomly formed solder bridges 36, and the solder scattering 35 may be generated as a result.

On the other hand, according to the semiconductor chip 40 according to the example, the second region R2 of the protective film 150-7 and the protective film 150-8 is spaced apart from the protective film 150-4 and adjacent to the protective film 150-2 and the protective film 150-1. This can control the solder bridge 36 to be formed at a position spaced apart from the protective film 150-4 and can prevent the solder scattering 35 from reaching the protective film 150-2 and the protective film 150-1.

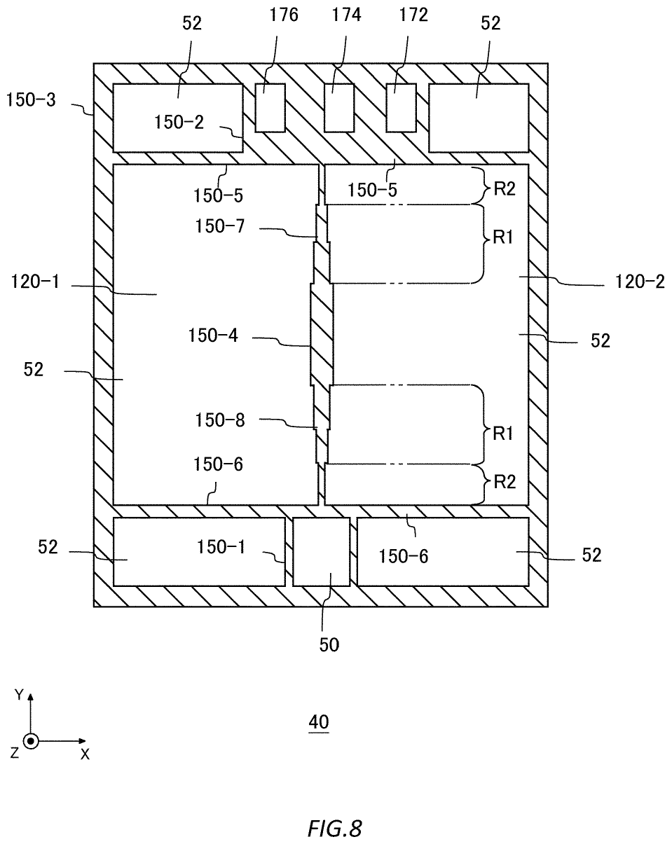

FIG. 8 is another example of a top view of the semiconductor chip 40 according to the example. Here, a member common with the semiconductor chip 40 according to the example is indicated by the same sign and the description thereof is omitted. The protective film 150-7 and the protective film 150-8 of the present example have a stepped shape in a top view. That is, the width of the protective film 150-7 and the protective film 150-8 of the present example gradually decrease in a stepped shape as being more spaced apart from the protective film 150-4.

In this manner, the protective film 150-7 and the protective film 150-8 are formed to have a stepped shape such that a position at which the solder bridge 36 is formed in the second region R2 can easily be controlled. Note that the width and the length of each of the first region R1 and the second region R2 are within the numerical range described in connection with the aforementioned example such that the aforementioned effect to prevent the solder scattering can be obtained.

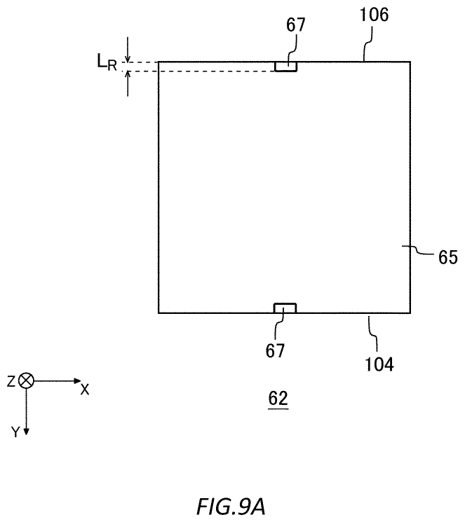

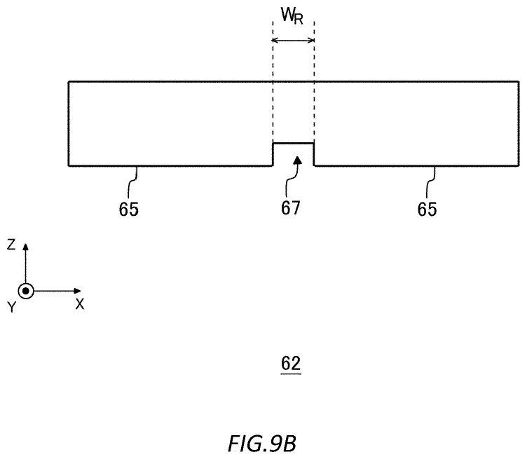

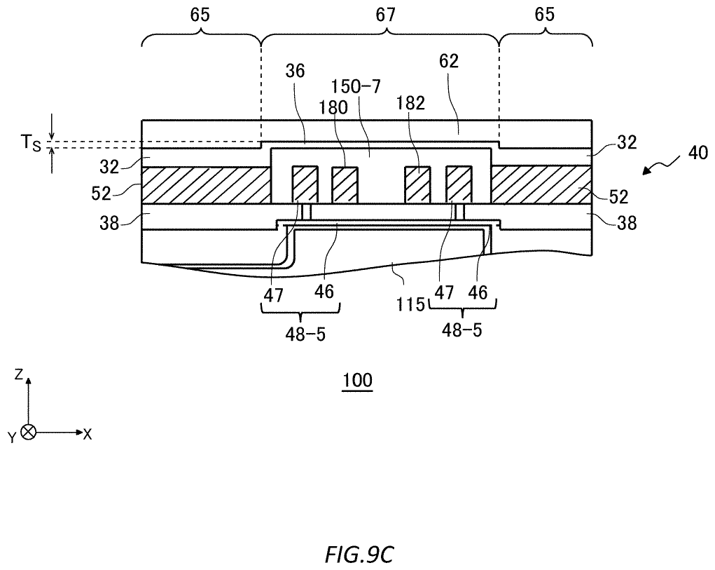

FIG. 9A is an example of a bottom view of the chip connecting portion 62. FIG. 9B is an example of a cross sectional view of the chip connecting portion 62. The chip connecting portion 62 of the present example may include, on a lower surface working as a surface bonded with the semiconductor chip 40, a main surface portion 65 for bonding with a semiconductor device and a concave portion 67 provided at an end portion of the main surface portion 65. FIG. 9B is an XZ plane passing through the concave portion 67.

The concave portion 67 is provided to correspond to the protective film 150-7. That is, the concave portion 67 is provided at the second end side 106 of the chip connecting portion 62 at a position which overlaps with the second region R2 of the protective film 150-7. The main surface portion 65 is in contact with the protective film 150. A plurality of concave portions 67 may be provided to correspond to the protective film 150-7 and the protective film 150-8. In this case, the concave portions 67 are provided at opposing positions at the first end side 104 and the second end side 106 of the chip connecting portion 62.

A length L_{R} of the concave portion 67 in the Y axis direction is equal to or greater than 100 μm and equal to or smaller than 2000 μm. The concave portion 67 shown in FIG. 9B has a rectangular cross section, although not limited thereto. A width W_{R} of an upper end of the concave portion 67 may be narrower than a width of a lower end. The width W_{R} is equal to or greater than 100 μm and equal to or smaller than 500 μm.

FIG. 9C is an example of a cross sectional view of a protective film 150-7 of the semiconductor module 100. FIG. 9C is an XZ plane passing through the second region R2 of the protective film 150-7, the chip connecting portion 62, the solder portion 32, the emitter electrode 52, the anode wiring 180, the cathode wiring 182 and the gate runner 48-4. The chip connecting portion 62 of the present example includes, on the bonding surface, the main surface portion 65 and the concave portion 67. Note that the XZ plane passing through the second region R2 of the protective film 150-8 is the same as the XZ plane passing through the second region R2 of the protective film 150-7, aside from the anode wiring 180 and the cathode wiring 182 being not included, and therefore the illustration thereof is omitted.

The main surface portion 65 of the present example is in contact with the upper surface of the protective film 150-7. In the concave portion 67 of the present example, the solder bridge 36 extending from the solder portion 32 is provided between the chip connecting portion 62 and the protective film 150-7. A thickness T_{S} of the solder bridge 36 is equal to or greater than 20 μm and equal to or smaller than 500 μm. The concave portion 67 is provided such that, when the chip connecting portion 62 is connected to the semiconductor chip 40 via the solder portion 32, the solder portion 32 easily extends in the concave portion 67 and the solder bridge 36 is formed between the chip connecting portion 62 and the protective film 150-7. This can lead to the effect to prevent from solder scattering, similarly to the aforementioned example.

While the present invention has been described by way of the embodiments, the technical scope of the present invention is not limited to the above described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each process performed by an apparatus, system, program, and method shown in the claims, embodiments, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: resin casing, 12: sealing resin, 20: cooling apparatus, 21: dielectric substrate, 26: circuit pattern, 30: solder portion, 32: solder portion, 33: fillet portion, 34: void, 35: solder scattering, 36: solder bridge, 40: semiconductor chip, 38: interlayer dielectric film, 46: polysilicon wiring, 47: metal wiring, 48: gate runner, 50: gate pad, 52: emitter electrode, 60: lead frame, 62: chip connecting portion, 64: bridge portion, 65: main surface portion, 66: circuit pattern connecting portion, 67: concave portion, 68: leg portion, 94: space, 100: semiconductor module, 102: end side, 104: first end side, 106: second end side, 110: semiconductor substrate, 111: first well region, 112: second well region, 113: peripheral well region, 114: dividing well region, 115: wider portion, 120: active portion, 150: protective film, 172: current detection pad, 174: anode pad, 176: cathode pad, 178: temperature sensing portion, 180: anode wiring, 182: cathode wiring

What is claimed is:

1. A semiconductor device comprising:
a temperature sensing portion provided above a semiconductor substrate;
a temperature sensing wiring portion electrically connected to the temperature sensing portion; and
a protective film including a temperature sensing protective film provided above the temperature sensing portion and a first wiring protective film provided above the temperature sensing wiring portion, wherein
the first wiring protective film includes:
a first region adjacent to the temperature sensing protective film; and
a second region provided more spaced apart from the temperature sensing protective film than the first region and having a width narrower than that of the first region.

2. The semiconductor device according to claim 1, wherein a width of the first wiring protective film gradually decreases as being more spaced apart from the temperature sensing protective film.

3. The semiconductor device according to claim 1, wherein the first wiring protective film has a trapezoidal shape in a top view.

4. The semiconductor device according to claim 1, wherein the first wiring protective film has a stepped shape in a top view.

5. The semiconductor device according to claim 1, wherein a width of the second region is equal to or greater than 5 μm and equal to or smaller than 500 μm.

6. The semiconductor device according to claim 1, wherein a length of the second region in an extending direction of the temperature sensing wiring portion is equal to or greater than 500 μm and equal to or smaller than 5000 μm.

7. The semiconductor device according to claim 1, wherein the protective film includes a second wiring protective film extending from the temperature sensing protective film in a direction different from an extending direction of the first wiring protective film.

8. The semiconductor device according to claim 7, comprising a gate wiring portion provided above the semiconductor substrate, wherein
the second wiring protective film is provided above the gate wiring portion.

9. The semiconductor device according to claim 8, wherein the second wiring protective film includes the first region and the second region.

10. The semiconductor device according to claim 1, wherein the temperature sensing portion is provided at a center of the semiconductor substrate in a top view.

11. The semiconductor device according to claim 10, comprising a temperature sensing pad electrically connected to the temperature sensing wiring portion in a peripheral region of the semiconductor substrate.

12. The semiconductor device according to claim 1, wherein the temperature sensing wiring portion includes a cathode wiring portion and an anode wiring portion.

13. A semiconductor module comprising:
the semiconductor device according to claim 1;
a lead frame including a concave portion on a surface bonded with the semiconductor device;
a solder portion for bonding the lead frame and the semiconductor device, wherein
the lead frame is disposed on the semiconductor device such that the concave portion corresponds to the first wiring protective film.

14. A semiconductor module comprising:
the semiconductor device according to claim 2;
a lead frame including a concave portion on a surface bonded with the semiconductor device;
a solder portion for bonding the lead frame and the semiconductor device, wherein
the lead frame is disposed on the semiconductor device such that the concave portion corresponds to the first wiring protective film.

15. The semiconductor module according to claim 13, wherein the concave portion is provided to correspond to the second region of the first wiring protective film.

16. The semiconductor module according to claim 13, wherein
the concave portion is provided at an end portion of the lead frame, and
the semiconductor module comprises a solder bridge provided between the lead frame and the first wiring protective film in the concave portion to extend from the solder portion.

17. The semiconductor module according to claim 16, wherein
a thickness of the solder bridge is equal to or greater than 20 μm and equal to or smaller than 500 μm.

18. The semiconductor module according to claim 16, wherein the bonding surface includes:
a main surface portion for being bonded to the semiconductor device; and
the concave portion provided at an end portion of the main surface portion, and wherein
the lead frame is disposed on the semiconductor device such that the main surface portion is in contact with the first wiring protective film.

19. The semiconductor module according to claim 13, wherein
a width of an upper end of the concave portion is equal to or greater than 100 μm and equal to or smaller than 500 μm.

20. A lead frame comprising a bonding surface bonded to a semiconductor device via a solder portion, wherein
the bonding surface includes:
a main surface portion for being bonded to the semiconductor device; and
a concave portion provided at an end portion of the main surface portion.
